(19) United States
(12) Patent Application Publication
(10) Pub. No.: US 2007/0026586 A1
(43) Pub. Date: Feb. 1, 2007

(54) Mask for manufacturing a display substrate capable of improving image quality

(75) Inventors: Hyuk-Jin Kim, Gyeonggi-do (KR); Min-Wook Park, Asan-si (KR); In-Woo Kim, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/494,085

(22) Filed: Jul. 26, 2006

(30) Foreign Application Priority Data
Jul. 26, 2005 (KR) 2005-67957

(51) Int. Cl. H01L 21/84

(52) U.S. Cl. 438/152

(57) ABSTRACT

A mask for forming a display substrate capable of improving color reproducibility by avoiding color spots and color shifts is presented. The mask includes a first sub-mask, a second sub-mask, a first overlapping portion and a second overlapping portion. The first sub-mask includes color reticles to form color pixels in a first active region of a display substrate. The second sub-mask includes color reticles to form color pixels in a second active region of the display substrate. The first overlapping portion is on a portion of the first sub-mask that overlaps the second sub-mask. The color reticles in the first overlapping portion are arranged at a different density from the rest of the first sub-mask. The second overlapping portion is on a portion of the second sub-mask that overlaps the first sub-mask. The color reticles in the second overlapping portion are arranged at a substantially same density as the first overlapping portion. Therefore, image display quality is improved.

### CROSS-REFERENCE TO RELATED APPLICATION

The present application claims priority from Korean Patent Application No. 2005-67957, filed on Jul. 26, 2005, the disclosure of which is hereby incorporated herein by reference in its entirety.

### BACKGROUND OF THE INVENTION

1. Field of the Invention

The present invention relates to a mask, a method of manufacturing a display substrate using the mask and a display substrate. More particularly, the present invention relates to a mask capable of improving a color reproducibility of a display device, a method of manufacturing a display substrate using the mask and a display substrate.

2. Description of the Related Art

A liquid crystal display (LCD) device, in general, includes an array substrate, a color filter substrate and a liquid crystal layer between the two substrates. The array substrate includes a gate line, a source line and a switching element electrically connected to the gate and source lines. The color filter substrate includes a color filter pattern and a common electrode. Liquid crystals of the liquid crystal layer change their arrangement in response to an electric field applied thereto, and thus light transmittance through the liquid crystal layer is changed.

The patterns of the array substrate are formed through photolithography processes. In each of the photolithography processes, a mask having reticles is aligned on a base substrate, and an ultraviolet light is irradiated onto the base substrate through the mask so that the reticles are printed on the base substrate.

The current trend is for the LCD panel of the LCD device to become larger. In a large LCD device (e.g., more than about forty inches), the array substrate is manufactured using a plurality of masks in each of the photolithography processes. Each of the photolithography processes is performed using a mask having at least two shots of the ultraviolet light.

When the array substrate is patterned using a mask and at least two shots of ultraviolet light, the adjacent shots overlap in a portion of the base substrate. A spot is formed in an active region of the LCD panel corresponding to the overlapped region. The overlapped region adversely affects the quality of the image displayed because of color spot formation and color shift in the active region. It would be desirable to avoid this negative effect on image quality.

### SUMMARY OF THE INVENTION

The present invention provides a mask capable of improving a color reproducibility of a display device. The present invention also provides a method of manufacturing a display substrate using the above-mentioned mask. The present invention also provides a display substrate.

In one aspect, the invention is a mask that includes a first sub-mask, a second sub-mask, a first overlapping portion and a second overlapping portion. The first sub-mask includes a plurality of color reticles to form color pixels in a first active region of a display substrate. The second sub-mask includes a plurality of color reticles to form color pixels in a second active region of the display substrate. The first overlapping portion of the first sub-mask overlaps the second sub-mask. The first overlapping portion includes a plurality of color reticles that are arranged at a different density from the rest of the first sub-mask. The second overlapping portion of the second sub-mask overlaps the first sub-mask. The second overlapping portion includes a plurality of color reticles that are arranged at a substantially same density as the first overlapping portion.

In another aspect, the invention is a method of manufacturing a display substrate using a mask having a first sub-mask and a second sub-mask partially overlaps the first sub-mask. The overlapped portion of the first sub-mask includes color reticles that are arranged at a substantially same density as the overlapped portion of the second sub-mask. The method entails forming a pixel layer on a base substrate and patterning the pixel layer. The pixel layer is patterned using the first sub-mask to form first pixel patterns in a first active region and an overlapped region of the base substrate. The overlapped region corresponds to the first overlapping portion. The pixel layer is patterned using the second sub-mask to form second pixel patterns in a second active region and the overlapped region of the base substrate.

In yet another aspect, the invention is a display substrate manufactured using a mask having a first sub-mask and a second sub-mask that partially overlaps the first sub-mask. The display substrate includes a plurality of first pixels and a plurality of second pixels. The overlapped portion of the first sub-mask includes color reticles arranged at a substantially equal density as the overlapped portion of the second sub-mask. The first pixels are in a first active region and an overlapped region. The first active region and the overlapped region are formed with the first sub-mask. The second pixels are in a second active region and the overlapped region. The second active region and the overlapped region are formed with the second sub-mask.

According to the present invention, a ratio between the red, green and blue reticles of a mask is controlled to decrease the color spot and the color shift in the overlapped region of the sub-masks.

### BRIEF DESCRIPTION OF THE DRAWINGS

The above and other advantages of the present invention will become more apparent by describing in detail exemplary embodiments thereof with reference to the accompanying drawings, in which:

FIG. 1 is a plan view showing a mask in accordance with one embodiment of the present invention;

FIG. 2 is a plan view showing a display substrate manufactured using the mask shown in FIG. 1;

FIGS. 3A and 3B are enlarged plan views of the mask in FIG. 1;

FIGS. 4A and 4B are enlarged plan views of a mask in accordance with another embodiment of the present invention;

FIG. 5 is an enlarged plan view showing the portion ‘A’ of FIGS. 3A and 3B;

FIG. 6 is a cross-sectional view taken along the line I-I′ of FIG. 5;

FIGS. 7A and 7B are cross-sectional views showing formation of gate metal patterns in an overlapped region of a display substrate using a first mask in accordance with one embodiment of the present invention;

FIGS. 8A and 8B are cross-sectional views showing formation of channel parts in the overlapped region of the display substrate as shown in FIGS. 7A and 7B using a second mask;

FIGS. 9A and 9B are cross-sectional views showing formation of source metal patterns in the overlapped region of the display substrate as shown in FIGS. 8A and 8B using a third mask; and

FIGS. 10A and 10B are cross-sectional views showing formation of pixel electrodes in the overlapped region of the display substrate as shown in FIGS. 9A and 9B using a fourth mask.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

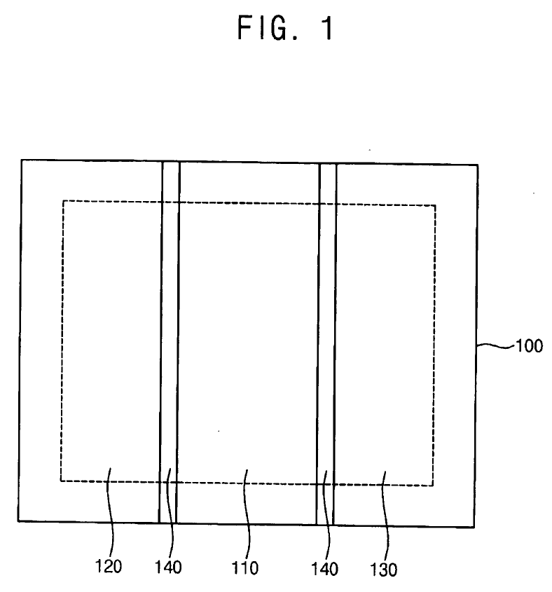

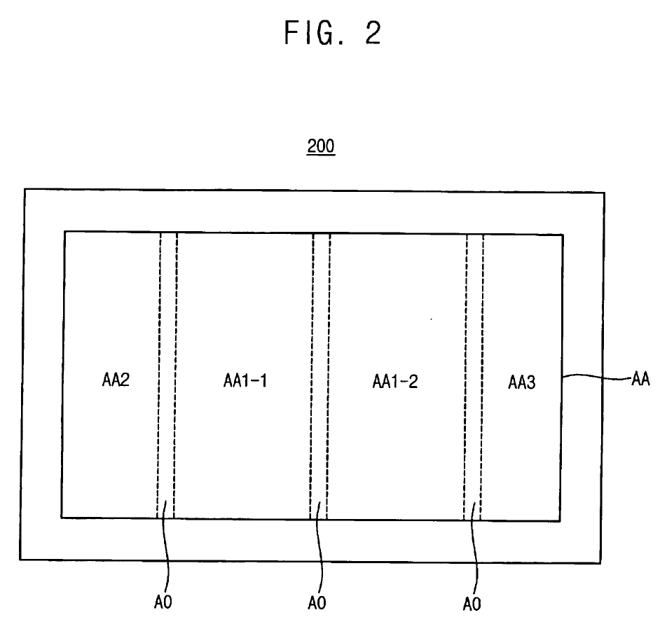

FIG. 1 is a plan view showing a mask in accordance with one embodiment of the present invention. FIG. 2 is a plan view showing a display substrate manufactured using the mask as shown in FIG. 1.

Referring to FIGS. 1 and 2, the mask 100 includes a first sub-mask 110, a second sub-mask 120, a third sub-mask 130 and an overlapping portion 140. Reticles are formed in each of the first, second and third sub-masks 110, 120 and 130 to pattern an active region AA of the display substrate 200 through a photolithography process. The overlapping portion 140 is between regions that are covered by one of the sub-masks or one of the first, second and third sub-masks 110, 120 and 130. Hereinafter, a first shot, a second shot and a third shot of ultraviolet light represent shots with the first, second and third sub-masks 110, 120 and 130, respectively.

The first shot 110 is on a central portion of the mask 100. The second shot 120 is on a left side of the first shot 110. The third shot 130 is on a right side of the first shot 110. “Left” and “right” are used herein with reference to FIG. 1.

The display substrate 200 is irradiated two times with ultraviolet light through the first shot 110. The first irradiation forms a first central region AA1-1, and the second irradiation forms a second central region AA1-2. The central portions regions AA1-1 and AA1-2 are parts of an active region AA. The ultraviolet light is shined onto the display substrate 200 to the left of the first and second central regions AA1-1 and AA1-2 to form a left region AA2. The ultraviolet light is shined onto the display substrate 200 to the right of the first and second central regions AA1-1 and AA1-2 to form a right region M3. As shown in FIG. 2, the left region AA2 and the right region AA3 are each a part of the active region M.

When exposing the display substrate 200 to ultraviolet light, the overlapping portion 140 of the mask 100 is used to form the overlapped region A0 of the active region M. The overlapping portion 140 lies at borders between the first and second sub-masks 110, 120 and between second and third submasks 120, 130 that neighbor each other.

The overlapping portion 140 includes a first overlapping portion that is formed by an edge of the first sub-mask 110 and a second overlapping portion that is formed by an edge of the second sub-mask 120. A first stitch pattern and a second stitch pattern are formed on the first and second overlapping portions. A “stitch pattern” is a layout of reticles.

The second stitch pattern has an opposite pattern to the first stitch pattern. For example, the reticles in the first stitch pattern are formed closer together as they approach the second sub-mask 120. The reticles in the second stitch pattern are spaced apart more, as they approach the second sub-mask 120. That is, a density of the reticles in the first stitch pattern is increased, and a density of the reticles of the second stitch pattern is decreased. Alternatively, the reticles in the first stitch pattern may be formed closer together as they approach the second sub-mask 120, and the reticles in the second stitch pattern may be spaced apart more as they approach the second sub-mask 120. The reticles may be opening patterns or light blocking patterns.

The number of reticles corresponding to red color, the number of reticles corresponding to green color, and the number of reticles corresponding to blue color may be substantially the same in each of the first and second stitch patterns.

For example, the number of red reticles corresponding to red pixels in the first stitch pattern is substantially the same as the number of red reticles corresponding to red pixels in the second stitch pattern. In addition, the number of green reticles corresponding to green pixels and the number of blue reticles corresponding to blue pixels in the first stitch pattern are substantially the same as the number of green reticles corresponding to green pixels and the number of blue reticles corresponding to blue pixels in the second stitch pattern, respectively.

The number of red reticles, the number of green reticles and the number of blue reticles may be substantially the same in the first stitch pattern. In addition, the number of the red reticles, the number of the green reticles and the number of the blue reticles may be substantially the same in the second stitch pattern.

In FIGS. 1 and 2, the number of the red, green and blue reticles in the first stitch pattern are substantially the same as the number of the red, green and blue reticles in the second stitch pattern to decrease a color spot and a color shift in the overlapped region A0.

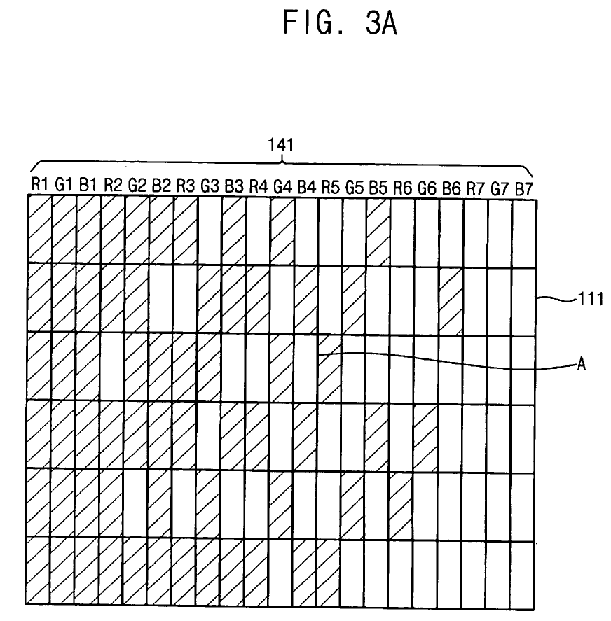

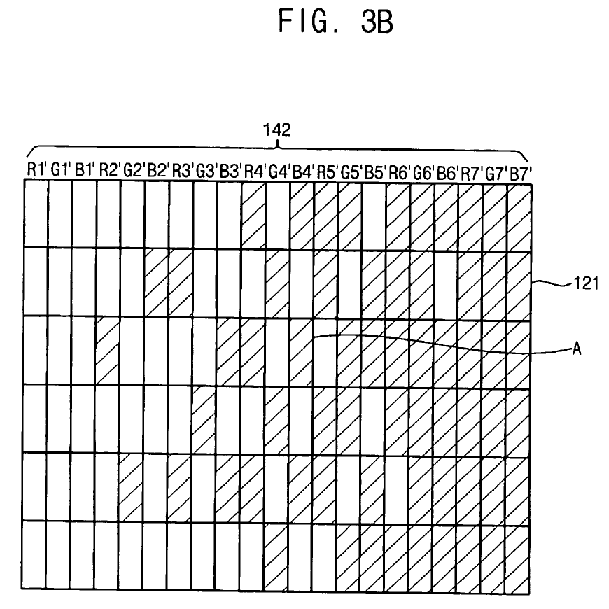

FIGS. 3A and 3B are enlarged plan views of the mask in FIG. 1.

FIG. 3A is an enlarged plan view showing the first stitch pattern 111 on a first overlapping portion 141 of the first sub-mask 110. FIG. 3B is an enlarged plan view showing the second stitch pattern 121 on a second overlapping portion 142 of the second sub-mask 120. In FIGS. 3A and 3B, the patterned structure has 21×7 pixels.

Referring to FIGS. 1 to 3B, the first overlapping portion 141 is overlapped with the second overlapping portion 142. In particular, the R1 column of the first stitch pattern 111 is overlapped with the R1′ column of the second stitch pattern 121, and the B7 column of the first stitch pattern 111 is overlapped with the B7′ column of the second stitch pattern 121 so that the 21×7 pixels of the first stitch pattern 111 are overlapped with the 21×7 pixels of the second stitch pattern 121.

The R1 column of the first stitch pattern 111 contains red reticles. In contrast, there are no red reticles on the R1′ column of the second stitch pattern 121. As shown, there are six red reticles in the R1 column but no red reticles in the R1′ column. As the reticles are not formed on the R1′ column of the second stitch pattern 121, the pixel patterns of the display substrate 200 corresponding to the R1 column or the R1′ column are formed by the first stitch pattern 111. The pixel patterns include gate lines, source lines, switching elements and pixel electrodes.

The G1 column of the first stitch pattern 111 contains green reticles. In contrast, there are no green reticles on the G1′ column of the second stitch pattern 121. As shown, there are six green reticles on the G1 column but no green reticles in the G1′ column.

Similarly, the B1 column of the first stitch pattern 111 contains blue reticles. In contrast, there are no blue reticles on the B1′ column of the second stitch pattern 121. As shown, there are six blue reticles on the B1 column but no blue reticles in the B1′ column.

There are five red reticles in the R2 column of the first stitch pattern 111 and one red reticle in the R2′ column of the second stitch pattern 121. The red reticles in the R2 column of the first stitch pattern 111 complement the red reticle in the R2′ column of the second stitch pattern 121.

Similarly, there are five green reticles in the G2 column of the first stitch pattern 111 and one green reticle in the G2′ column of the second stitch pattern 121. The green reticles in the G2 column of the first stitch pattern 111 complement the green reticle in the G2′ column of the second stitch pattern 121. Blue reticles in the B2 column and B2′ column are similarly arranged. There are five blue reticles in the B2 column of the first stitch pattern 111 and one blue reticle in a B2′ column of the second stitch pattern 121. The blue reticles in the B2 column of the first stitch pattern 111 complement the blue reticle in the B2′ column of the second stitch pattern 121.

There are four red reticles in the R3 column of the first stitch pattern 111 and two red reticles in the R3′ column of the second stitch pattern 121. The red reticles in the R3 column of the first stitch pattern 111 complement the red reticle of the R3′ column of the second stitch pattern 121.

Similarly, there are four green reticles in the G3 column of the first stitch pattern 111 and two green reticles in a G3′ column of the second stitch pattern 121. The green reticles in the G3 column of the first stitch pattern 111 complement the green reticle in the G3′ column of the second stitch pattern 121. Blue reticles in the B3 column and B3′ column are similarly arranged. There are four blue reticles in the B3 column of the first stitch pattern 111 and two blue reticles in the B3′ column of the second stitch pattern 121. The blue reticles in the B3 column of the first stitch pattern 111 complement the blue reticle in the B3′ column of the second stitch pattern 121.

The number of color reticles in the fourth, fifth, sixth, and seventh columns in the first overlapping portion 141 decreases one by one so that there is no color reticle in the seventh columns. The color reticles are reticles of the mask for forming the color pixels. For example, the color reticles may be opening patterns corresponding to the color pixels or light blocking patterns corresponding to the color pixels. The respective number of color reticles in the fourth, fifth, sixth, and seventh columns in the second overlapping portion 142 complements the number of color reticles in the corresponding column in the first overlapping portion 141.

Thus, there is no red reticle in the R7 column of the first stitch pattern 111 and six red reticles in the R7′ column of the second stitch pattern 121. There is no green reticle in the G7 column of the first stitch pattern 111, and six green reticles in the G7′ column of the second stitch pattern 121. There is no blue reticle in the B1 column of the first stitch pattern 111, and six blue reticles in the B7′ column of the second stitch pattern 121.

The number of red reticles in each of the columns R1, R2, . . . R7 gradually decreases from six to zero in the first stitch pattern 111. The number of red reticles in each of the columns R1′, R2′, . . . R7′ gradually increases from zero to six in the second stitch pattern 121. There are twenty-one red reticles in each of the first and second stitch patterns 111 and 121. That is, the number of the red reticles in the first stitch pattern 111 is substantially equal to the number of the red reticles in the second stitch pattern 121.

The number of green reticles in each of the columns G1, G2, . . . G7 gradually decreases from six to zero in the first stitch pattern 111. The number of green reticles in each of the columns G1′, G2′, . . . G7′ gradually increases from zero to six in the second stitch pattern 121. There are twenty-one green reticles in each of the first and second stitch patterns 111 and 121. Likewise, the number of blue reticles in each of the columns B1, B2, . . . B7 gradually decreases from six to zero in the first stitch pattern 111. The number of the blue reticles in each of the columns B1′, B2′, . . . B7′ gradually increases from zero to six in the second stitch pattern 121. There are twenty-one blue reticles in each of the first and second stitch patterns 111 and 121. The number of red, green and blue reticles in the first stitch pattern 111 is substantially equal to the number of the red, green and blue reticles in the second stitch pattern 121.

The number of pixels that are patterned by the first sub-mask 110 is substantially the same as the number of pixels that are patterned by the second sub-mask 120 in the overlapped region A0 of the display substrate. The first sub-mask 110 overlaps the second sub-mask 120 in the overlapping portion 140. In the overlapped region A0, the number of each of the red, green and blue pixels that are patterned by the first sub-mask 110 is substantially the same as the number of red, green and blue pixels that are patterned by the second sub-mask 120.

Therefore, the color stitch spot and the color shift are decreased in the overlapped region A0.

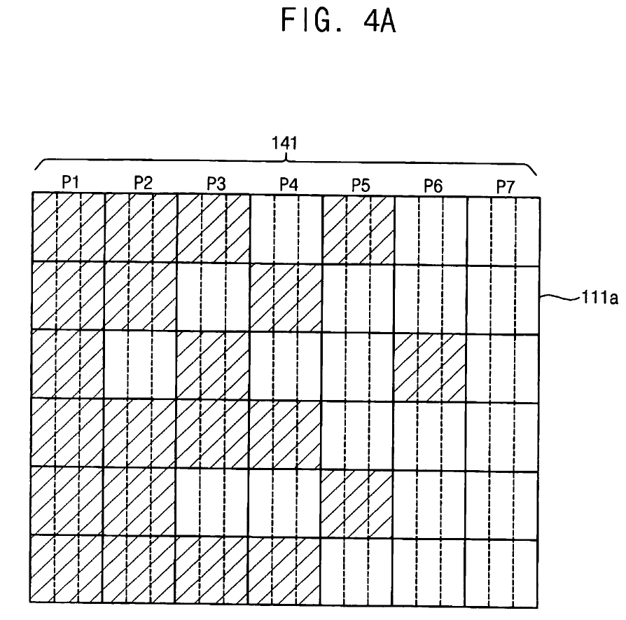

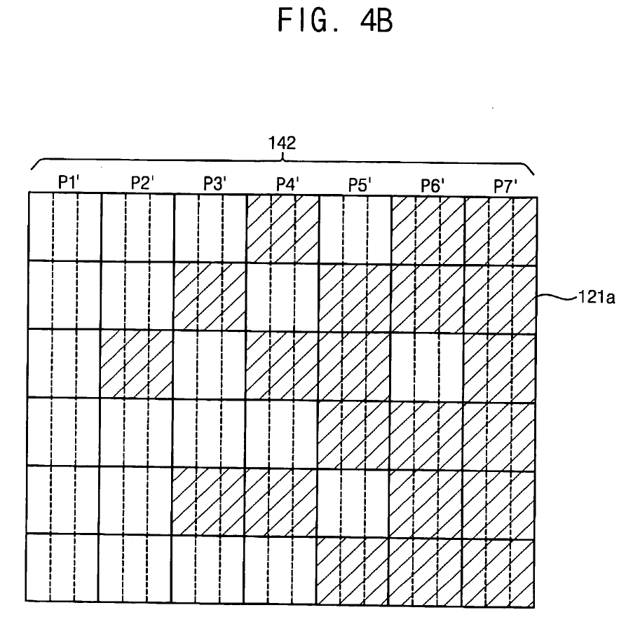

FIGS. 4A and 4B are enlarged plan views showing a mask in accordance with another embodiment of the present invention.

FIG. 4A is an enlarged plan view showing a first stitch pattern 111a on the first overlapping portion 141 of the first sub-mask 110. FIG. 4B is an enlarged plan view showing a second stitch pattern 121a on the second overlapping portion 142 of the second shot 120. In FIGS. 4A and 4B, a patterned structure has 7×7 pixels.

Referring to FIGS. 1, 2, 4A, and 4B, the first overlapping portion 141 overlaps the second overlapping portion 142. In particular, a P1 column of the first stitch pattern 111a overlaps a P1′ column of the second stitch pattern 121, and a P7 column of the first stitch pattern 111a overlaps the P7′ column of the second stitch pattern 121 so that the 7×7 pixels of the first stitch pattern 111 overlap the 7×7 pixels of the second stitch pattern 121.

The P1 column of the first stitch pattern 111a contains a reticle in every cell that could contain a reticle. In contrast, there is no reticle in the P1′ column of the second stitch pattern 121a. In the exemplary embodiment, there are six reticles in the P1 column. As there is no reticle in the P1′ column of the second stitch pattern 121a, pixel patterns in the region of the display substrate 200 that includes the P1 column and the P1′ column are formed by the first stitch pattern 111a. For example, each of the reticles includes red, green and blue reticle portions adjacent to each other.

There are five reticles in a P2 column of the first stitch pattern 111a, and one reticle in the P2′ column of the second stitch pattern 121a. The reticles in the P2 column of the first stitch pattern 111a complement the reticle in the P2′ column of the second stitch pattern 121a.

There is no reticle in the P7 column of the first stitch pattern 111a, whereas each cell in the P7′ column of the second stitch pattern 121a that could be filled with a reticle is filled with a reticle. In the exemplary embodiment, the number of reticles in the P7′ column is six.

The number of reticles in each of the columns P1, P2, . . . P7 gradually decreases from six to zero in the first stitch pattern 111a. The number of reticles in each of the columns P1′, P2′, . . . P7′ gradually increases from zero to six in the second stitch pattern 121a. There are twenty-one reticles in each of the first and second stitch patterns 111a and 121a. That is, the number of reticles in the first stitch pattern 111a is substantially equal to the number of reticles in the second stitch pattern 121a. The number of red, green and blue reticle portions in the first stitch pattern 111a is substantially equal to the number of red, green and blue reticle portions in the second stitch pattern 121a.

The number of pixels that are patterned by the first sub-mask 110 is substantially the same as the number of pixels that are patterned by the second sub-mask 120 in an overlapped region A0 of a display substrate. The first sub-mask 110 overlaps the second sub-mask 120 in the overlapping portion 140. In the overlapped region A0, the number of each of the red, green and blue pixels that are patterned by the first sub-mask 110 is substantially the same as the number of red, green and blue pixels that are patterned by the second sub-mask 120.

Therefore, a color stitch spot and the color shift are decreased in the overlapped region A0.

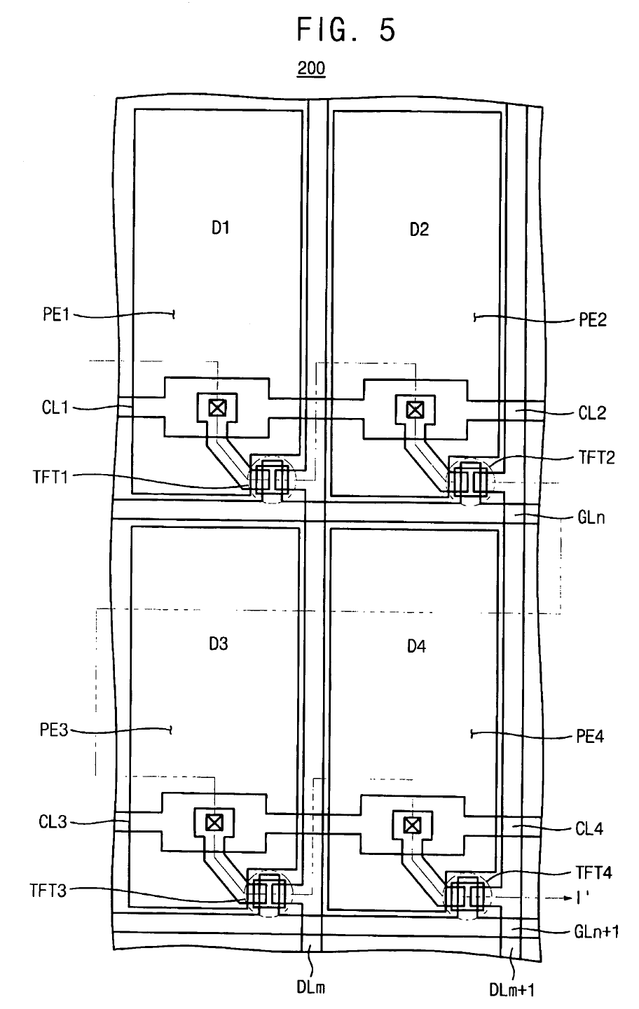

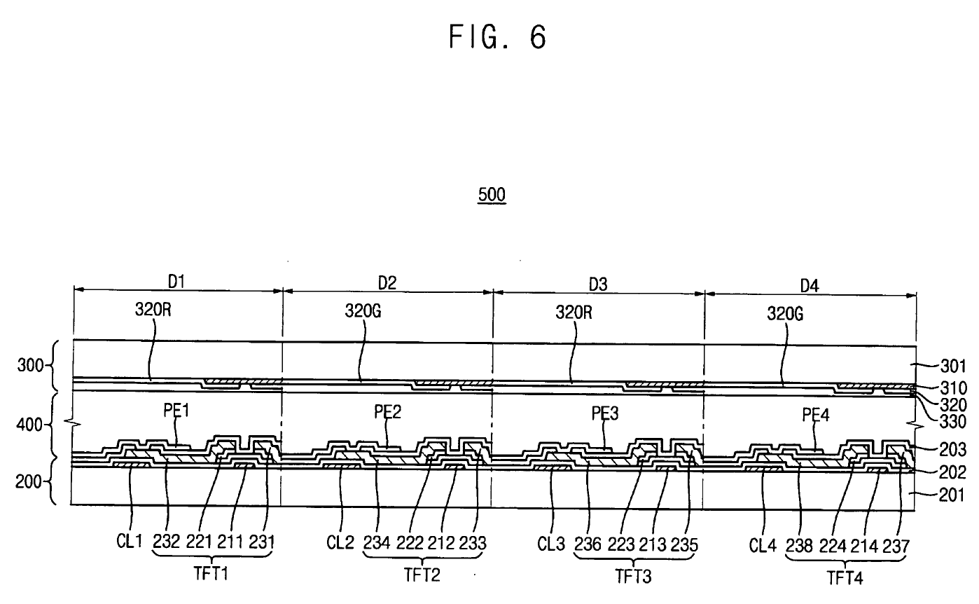

FIG. 5 is an enlarged plan view showing the portion ‘A’ in FIGS. 3A and 3B. FIG. 6 is a cross-sectional view taken along the I-I′ line in FIG. 5.

Referring to FIGS. 1 to 6, the display panel 500 includes the display substrate 200, a color substrate 300, and a liquid crystal layer 400. The color substrate 300 is designed to be assembled with the display substrate 200. The liquid crystal layer 400 is interposed between the display substrate 200 and the color substrate 300.

The display substrate 200 includes a first pixel D1, a second pixel D2, a third pixel D3 and a fourth pixel D4. The first and second pixels D1, D2 are adjacent to each other, as are the second and third pixels D2, D3 and the third and fourth pixels D3, D4.

The first and fourth pixels D1 and D4 are formed by the first stitch pattern 111 of the first sub-mask 110 shown in FIG. 3A, and the second and third pixels D2 and D3 are formed by the second stitch pattern 121 of the second sub-mask 120 shown in FIG. 3B.

In particular, the display substrate 200 includes a first base substrate 201, a plurality of gate lines GL1 and GL2, a plurality of source lines DL1 and DL2 and a plurality of pixels D1, D2, D3 and D4. The gate and source lines GL1, GL2, DL1 and DL2 are on the first base substrate 201. The pixels D1, D2, D3 and D4 are defined by the gate and source lines GL1, GL2, DL1 and DL2 adjacent to each other.

The first pixel D1 includes a first switching element TFT1, a first pixel electrode PE1 and a first storage line CL1. The first switching element TFT1 is electrically connected to an n-th gate line GLn and an m-th source line DLm. The first pixel electrode PE1 is electrically connected to the first switching element TFT1.

The first switching element TFT1 includes a first gate electrode 211, a first source electrode 231 and a first drain electrode 232. The first gate electrode 211 is electrically connected to the n-th gate line GLn. The first source electrode 231 is electrically connected to the m-th source line DLm. The first drain electrode 232 is electrically connected to the first pixel electrode PE1. A first channel part 221 is formed between the first source electrode 231 and the first drain electrode 232.

The second pixel D2 includes a second switching element TFT2, a second pixel electrode PE2 and a second storage line CL2. The second switching element TFT2 is electrically connected to the n-th gate line GLn and an (m+1)-th source line DLm+1. The second pixel electrode PE2 is electrically connected to the second switching element TFT2.

The second switching element TFT2 includes a second gate electrode 212, a second source electrode 233 and a second drain electrode 234. The second gate electrode 212 is electrically connected to the n-th gate line GLn. The second source electrode 233 is electrically connected to the (m+1)-th source line DLm+1. The second drain electrode 234 is electrically connected to the second pixel electrode PE2. A second channel part 222 is formed between the second source electrode 233 and the second drain electrode 234.

The third pixel D3 includes a third switching element TFT3, a third pixel electrode PE3 and a third storage line CL3. The third switching element TFT3 is electrically connected to an (n+1)-th gate line GLn+1 and the m-th source line DLm. The third pixel electrode PE3 is electrically connected to the third switching element TFT3.

The third switching element TFT3 includes a third gate electrode 213, a third source electrode 235 and a third drain electrode 236. The third gate electrode 213 is electrically connected to the (n+1)-th gate line GLn+1. The third source electrode 235 is electrically connected to the m-th source line DLm. The third drain electrode 236 is electrically connected to the third pixel electrode PE3. A third channel part 223 is formed between the third source electrode 235 and the third drain electrode 236.

The fourth pixel D4 includes a fourth switching element TFT4, a fourth pixel electrode PE4 and a fourth storage line CL4. The fourth switching element TFT4 is electrically connected to the (n+1)-th gate line GLn+1 and the (m+1)-th source line DLm+1. The fourth pixel electrode PE4 is electrically connected to the fourth switching element TFT4.

The fourth switching element TFT4 includes a fourth gate electrode 214, a fourth source electrode 237 and a fourth drain electrode 238. The fourth gate electrode 214 is electrically connected to the (n+1)-th gate line GLn+1. The fourth source electrode 237 is electrically connected to the (m+1)-th source line DLm+1.

The fourth drain electrode 238 is electrically connected to the fourth pixel electrode PE4. A fourth channel part 224 is formed between the fourth source electrode 237 and the fourth drain electrode 238.

A gate insulating layer 202 is formed on the first, second, third and fourth gate electrodes 211, 212, 213 and 214 and the first, second, third and fourth storage line CL1, CL2, CL3 and CL4. A passivation layer 203 is formed on the first, second, third and fourth source electrodes 231, 233, 235 and 237 and the first, second, third and fourth drain electrodes 232, 234, 236 and 238.

The color substrate 300 includes a second base substrate 301, a black matrix 310, a color filter layer 320 and a common electrode layer 330. The black matrix 310 is on the second base substrate 301.

The black matrix 310 is on a peripheral portion of the active region AA of the display substrate 200 to block any light leakage near the boundaries between the pixels D1, D2, D3 and D4. In addition, the black matrix 310 defines the boundaries of the pixels D1, D2, D3 and D4.

The color filter layer 320 includes red, green, and blue color filter patterns. Each of the red, green and blue color filter patterns is in each pixel region defined by the black matrix 310 to display a color image.

The common electrode layer 330 and the pixel electrodes PE1, PE2, PE3, PE4 form liquid crystal capacitors for the respective pixels D1, D2, D3 and D4.

The liquid crystal layer 400 is interposed between the display substrate 200 and the opposite substrate 300. Liquid crystals of the liquid crystal layer 400 change their arrangement in response to an electric field formed between the common electrode layer 330 and the pixel electrodes PE1, PE2, PE3 and PE4. Thus, light transmittance through the liquid crystal layer 400 is changed to display the desired image.

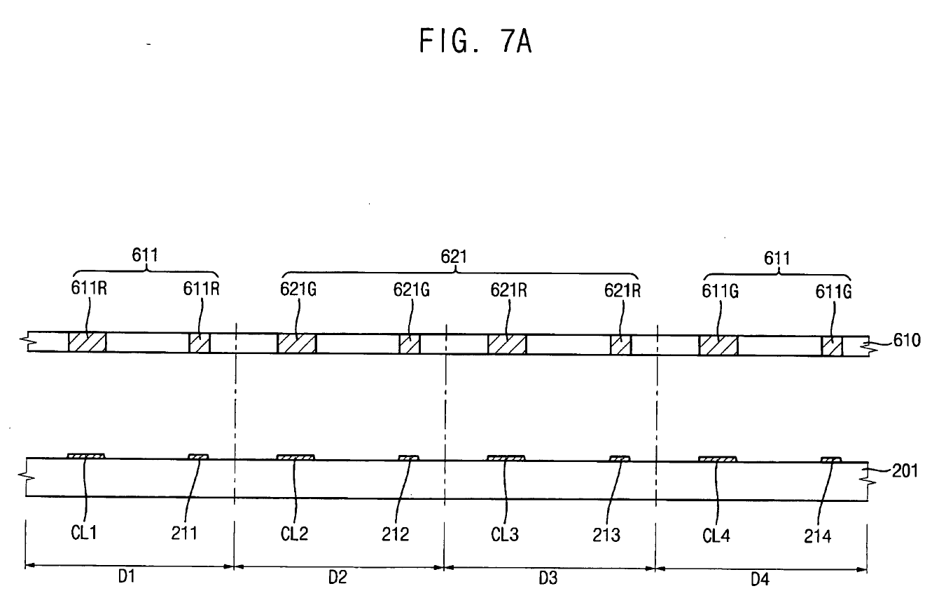

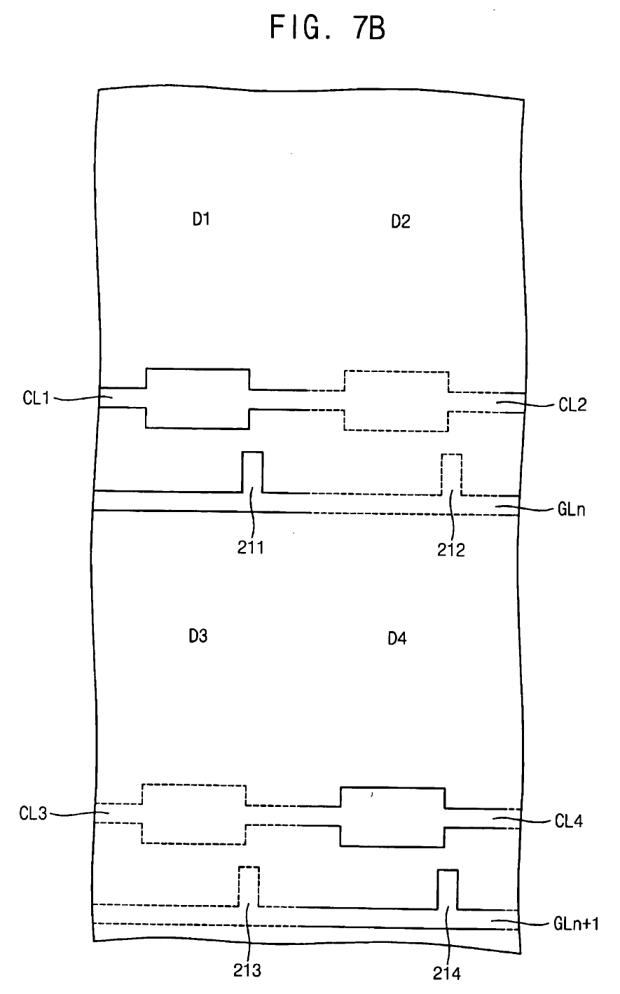

FIGS. 7A to 10B are cross-sectional views showing a method of manufacturing the display substrate shown in FIGS. 5 and 6 using the mask shown in FIG. 1. That is, the overlapped region A0 of the display substrate 200 is formed using the first stitch pattern 111 of the first sub-mask 110 and the second stitch pattern 121 of the second sub-mask 120.

FIGS. 7A and 7B are cross-sectional views showing a process for forming gate metal patterns in the overlapped region of the display substrate 200 using a first mask in accordance with one embodiment of the present invention.

Referring to FIGS. 5 to 7B, a gate metal layer is formed on the first base substrate 201. The gate metal layer is patterned through a photolithography process using a first mask 610 to form gate metal patterns.

In particular, the first mask 610 includes a first sub-mask 611 and a second sub-mask 612. The first sub-mask 611 includes first stitch patterns 611R and 611G. The second sub-mask 612 includes second stitch patterns 612R and 612G.

First gate patterns are formed in a metal layer using the first stitch patterns 611R and 611G. The first and fourth pixels D1 and D4 include the first gate patterns.

The first gate patterns include a first portion of the n-th gate line GLn for defining the first pixel D1, the first gate electrode 211 and the first storage line CL1. In addition, the first gate patterns further include a second portion of the (n+1)-th gate line GLn+1 for defining the fourth pixel D4, the fourth gate electrode 214 and the fourth storage line CL4.

Second gate patterns are formed in a metal layer using the second stitch patterns 612R and 612G of the first mask 610. The second and third pixels D2 and D3 include the second gate patterns.

The second gate patterns include a second portion of the n-th gate line GLn for defining the second pixel D2, the second gate electrode 212 and the second storage line CL2. In addition, the second gate patterns further include a first portion of the (n+1)-th gate line GLn+1 for defining the third pixel D3, the third gate electrode 213 and the third storage line CL3.

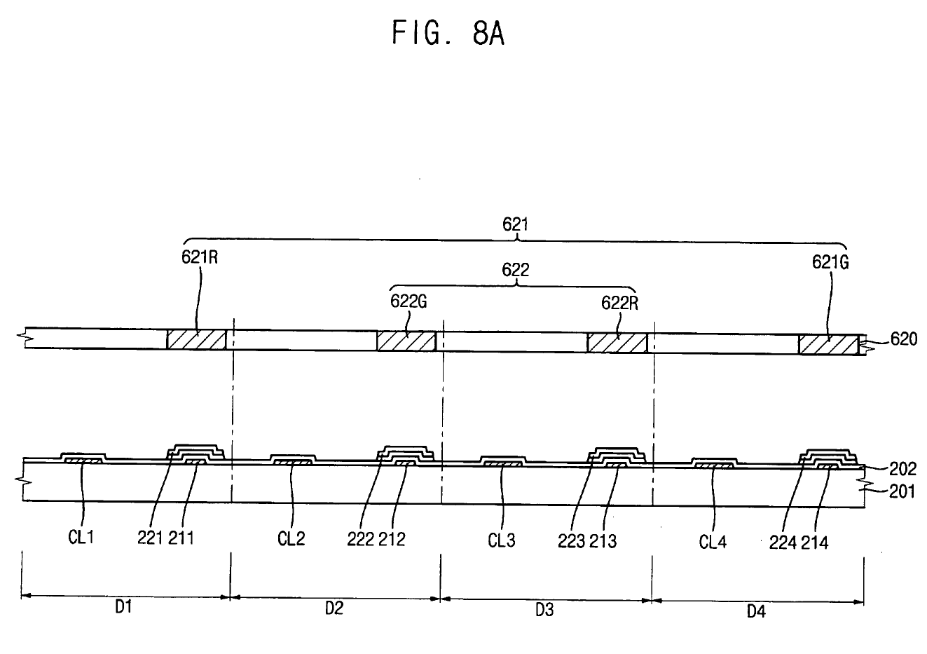

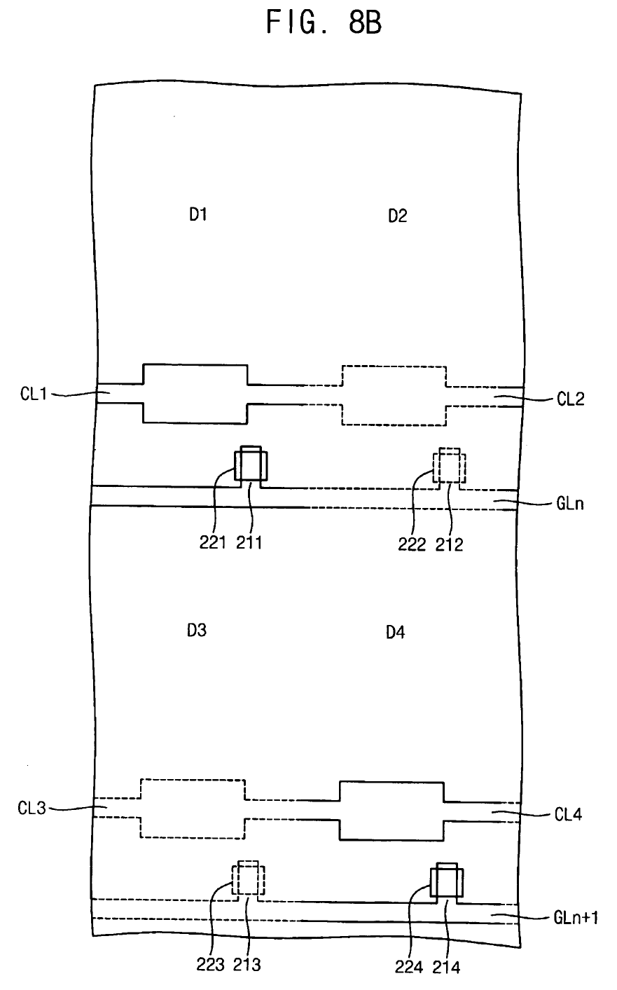

FIGS. 8A and 8B are cross-sectional views showing the formation of channel parts in the overlapped region A0 of the display substrate as shown in FIGS. 7A and 7B using a second mask.

Referring to FIGS. 4 to 8B, the gate insulating layer 202 is formed on the first base substrate 201 having the gate metal patterns. The gate insulating layer 202 contains an insulating material. Examples of the insulating material that can be used for the gate insulating layer 202 include silicon nitride, silicon oxide, etc.

A channel layer having an amorphous silicon layer and an n+ amorphous silicon layer is formed on the gate insulating layer 202. Impurities are doped into the amorphous silicon layer in situ to form the n+ amorphous silicon layer. The channel layer is patterned through a photolithography process using a second mask 620 to form the channel parts 221, 222, 223 and 224 of the switching elements TFT1, TFT2, TFT3 and TFT4.

In particular, the second mask 620 includes a first sub-mask 621 and a second sub-mask 622. The first sub-mask 621 includes first stitch patterns 621R and 621G. The second sub-mask 622 includes second stitch patterns 622R and 622G.

The first and fourth channel parts 221 and 224 of the first and fourth pixels D1 and D4 are formed using the first stitch patterns 621R and 621G. In addition, the second and third channel parts 222 and 223 of the second and third pixels D2 and D3 are formed using the second stitch patterns 622R and 622G.

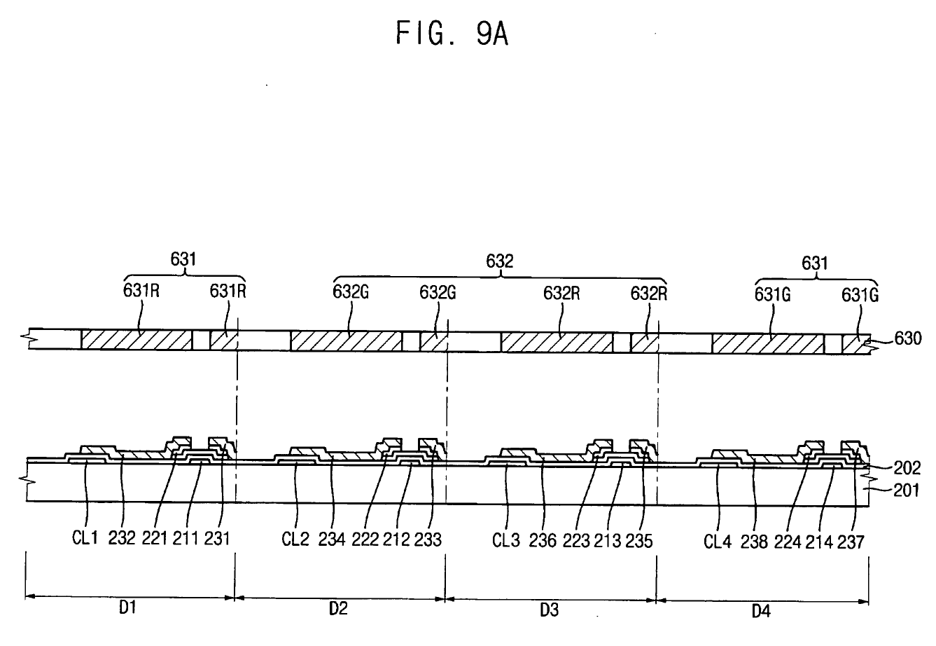

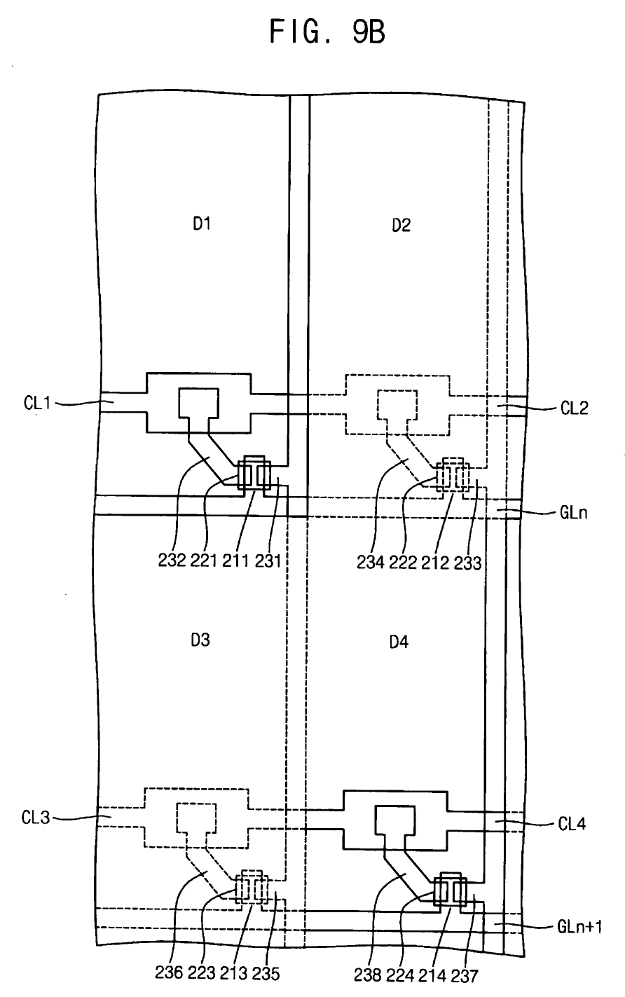

FIGS. 9A and 9B are cross-sectional views showing the formation of source metal patterns in the overlapped region A0 of the display substrate 200 as shown in FIGS. 8A and 8B using a third mask.

Referring to FIGS. 5 to 9B, a source metal layer is formed on the first base substrate 201 having the channel parts 221, 222, 223 and 224. The source metal layer is patterned through a photolithography process using a third mask 630.

In particular, the third mask 630 includes a first sub-mask 631 having first stitch patterns 631R and 631G and a second sub-mask 632 having second stitch patterns 632R and 632G.

First source patterns of the first and fourth pixels D1 and D4 are formed using the first stitch patterns 631R and 631G.

The first source patterns include a first portion of the m-th source line DLm for defining the first pixel D1, the first source electrode 231 and the first drain electrode 232. In addition, the first source patterns may further include a second portion of the (m+1)-th source line DLm+1 for defining the fourth pixel D4, the fourth source electrode 237 and the fourth drain electrode 238.

The second stitch patterns 632R and 632G correspond to the source patterns in the second and third pixels D2 and D3.

The source patterns include a first portion of the (m+1)-th data line DLm+1 for defining the second pixel D2, a second electrode 233 and a second drain electrode 234. The second gate patterns include a second portion of the m-th source line DLm for defining the third pixel D3, a source electrode 235 and a fourth drain electrode 236.

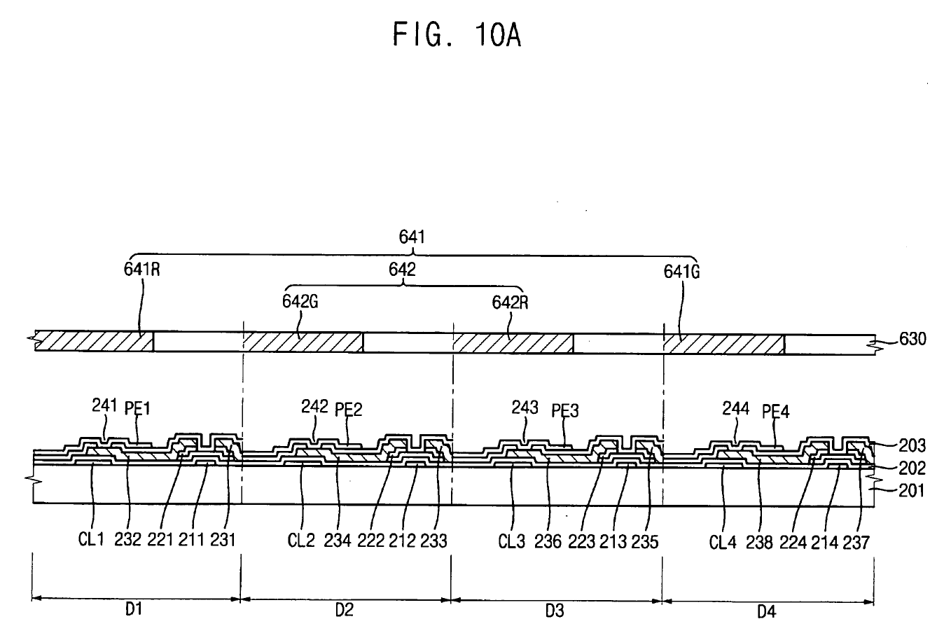

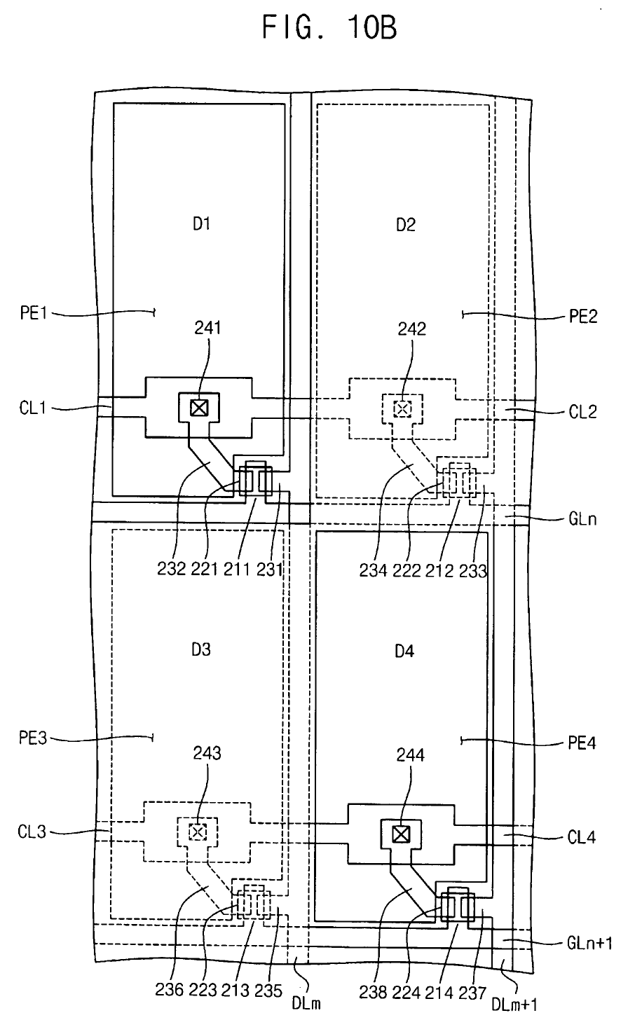

FIGS. 10A and 10B are cross-sectional views showing a process for forming pixel electrodes in the overlapped region A0 of the display substrate 200 shown in FIGS. 9A and 9B using a fourth mask.

Referring to FIGS. 5 to 10B, the passivation layer 203 is formed on the first base substrate 201 having the source metal patterns. The passivation layer 203 is partially removed to form contact holes 241, 242, 243 and 244 through which the first, second, third and fourth drain electrodes 232, 234, 236 and 238 are partially exposed, respectively.

The contact holes 241, 242, 243 and 244 are formed using a mask having first stitch patterns of the first sub-mask and second stitch patterns of the second sub-mask.

A pixel electrode layer is formed on the first base substrate 201 having the contact holes 241, 242, 243 and 244. The pixel electrode layer includes a transparent conductive material. Examples of the transparent conductive material that can be used for the pixel electrode layer include indium tin oxide (ITO), indium zinc oxide (IZO), indium tin-zinc oxide (ITZO), etc.

The pixel electrodes PE1, PE2, PE3 and PE4 are formed through a photolithography process using a fourth mask 640.

The fourth mask 640 includes a first sub-mask 641 having first stitch patterns 641R and 641G and a second sub-mask 642 having second stitch patterns 642R and 642G.

The first and fourth pixel electrodes PE1 and PE4 of the first and fourth pixels D1 and D4 are formed using the first stitch patterns 641R and 641G. The second and third pixel electrodes PE2 and PE3 of the second and third pixels D2 and D3 are formed using the second stitch patterns 642R and 642G.

According to the present invention, the density of the red, green and blue reticles in the overlapping portion at the border of neighboring sub-masks is controlled to decrease the color spot and the color shift in the active region of the display substrate. The “density” of color reticles refers to the number of color reticles in an overlapping portion. Therefore, a color reproducibility of the display device is increased to improve an image display quality of the display device.

This invention has been described with reference to the exemplary embodiments. It is evident, however, that many alternative modifications and variations will be apparent to those having skill in the art in light of the foregoing description. Accordingly, the present invention embraces all such alternative modifications and variations as fall within the spirit and scope of the appended claims.

What is claimed is:

1. A mask comprising:
a first sub-mask including a plurality of color reticles to form color pixels in a first active region of a display substrate;
a second sub-mask including a plurality of color reticles to form color pixels in a second active region of the display substrate;
a first overlapping portion of the first sub-mask that overlaps the second sub-mask, the first overlapping portion including a plurality of color reticles arranged at a different density from the rest of the first sub-mask; and
a second overlapping portion of the second sub-mask that overlaps the first sub-mask, the second overlapping portion including a plurality of color reticles has arranged at a substantially same density as the first overlapping portion.

2. The mask of claim 1, wherein the number of the color reticles in the first overlapping portion is substantially the same as the number of the color reticles in the second overlapping portion.

3. The mask of claim 1, wherein each of the first and second overlapping portions comprises first, second and third color reticles.

4. The mask of claim 3, wherein the number of each of the first, second and third color patterns in the first overlapping portion is substantially the same as the number of each of the first, second and third color patterns in the second overlapping portion.

5. The mask of claim 3, wherein the first, second and third color patterns comprise red, green and blue patterns.

6. The mask of claim 1, wherein a density of the first color patterns in the first overlapping portion increases, as the first color patterns get closer to a side of the first sub-mask.

7. The mask of claim 1, wherein a density of the second color patterns of the second overlapping portion decreases as the second color patterns get closer to a side of the second sub-mask.

8. The mask of claim 1, wherein each of the first and second color patterns comprises a black matrix that blocks light.

9. A method of manufacturing a display substrate using a mask having a first sub-mask and a second sub-mask that partially overlaps the first sub-mask, the first sub-mask including a first overlapping portion with color reticles that are arranged at a substantially same density as a second overlapping portion in the second sub-mask, the method comprising:
forming a pixel layer on a base substrate;
patterning the pixel layer using the first sub-mask to form first pixel patterns in a first active region and an overlapped region of the base substrate, the overlapped region corresponding to the first overlapping portion of the first sub-mask; and
patterning the pixel layer using the second sub-mask to form second pixel patterns in a second active region and the overlapped region of the base substrate.

10. The method of claim 9, wherein the number of the first pixel patterns is substantially equal to the number of the second pixel patterns in the overlapped region.

11. The method of claim 9, wherein the first and second pixel patterns comprise red, green and blue pixel regions.

12. The method of claim 9, wherein a density of the first pixel patterns in the overlapped region increases in a first direction.

13. The method of claim 12, wherein a density of the second pixel patterns in the overlapped region increases in a second direction that is opposite to the first direction.

14. The method of claim 9, wherein the pixel layer comprises a gate metal layer, a source metal layer, a channel layer, a passivation layer or a pixel electrode layer.

15. A display substrate manufactured using a mask having a first sub-mask and a second sub-mask that partially overlaps the first sub-mask, the overlapped portion of the first sub-mask including color reticles arranged at a substantially equal density as the overlapped portion of the second sub-mask, the display substrate comprising:
a plurality of first pixels in a first active region and an overlapped region, the first active region and the overlapped region formed with the first sub-mask; and
a plurality of second pixels in a second active region and the overlapped region, the second active region and the overlapped region formed with the second sub-mask.

16. The display substrate of claim 15, wherein the number of the first pixels is substantially equal to the number of the second pixels in the overlapped region.

17. The display substrate of claim 15, wherein each of the first and second pixels comprises red, green and blue pixels.

18. The display substrate of claim 17, wherein a number of each of the red, green and blue pixels of the first pixels is substantially equal to a number of each of the red, green and blue pixels of the second pixels in the overlapped region.
